(19) United States
(12) Patent Application Publication
(10) Pub. No.: US 2025/0300045 A1
(43) Pub. Date: Sep. 25, 2025

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Kenta NAKAHARA, Tokyo (JP)

(73) Assignee: Mitsubishi Electric Corporation, Tokyo (JP)

(21) Appl. No.: 18/860,788

(22) PCT Filed: Aug. 17, 2022
(86) PCT No.: PCT/JP2022/031026

§ 371 Date: Oct. 28, 2024

(51) Int. Cl. H01L 23/498; H01L 21/48

(52) U.S. Cl. CPC H01L 23/49811; H01L 21/4842

(57) ABSTRACT

An object is to provide a technology that can suppress a misalignment when an electrode terminal is mounted on a circuit pattern of an insulating substrate. A semiconductor device includes: an insulating substrate on an upper surface of which a circuit pattern is formed; a semiconductor element mounted on the circuit pattern; and an electrode terminal which includes a junction bonded to an upper surface of the circuit pattern and which is electrically connected to the semiconductor element, wherein the circuit pattern includes a fitting portion, and the junction of the electrode terminal includes a fitted portion to be fitted into the fitting portion.

### TECHNICAL FIELD

The present disclosure relates to a semiconductor device, and a method for manufacturing the semiconductor device.

### BACKGROUND ART

Conventionally, forming pads each with a step on an insulating substrate and mounting a lead (corresponding to an electrode terminal) to fit the step of each of the pads prevent misalignments of the leads (for example, see Patent Document 1).

### PRIOR ART DOCUMENT

### Patent Document

Patent Document 1: Japanese Patent Application Laid-Open No. H5-67871

### SUMMARY

### Problem to be Solved by the Invention

However, the steps of the pads described in Patent Document 1 are provided for preventing solder flow in a reflow process. Each of the steps is sized larger than a joint of the lead by the solder applied to the step. Thus, a misalignment easily occurs when the leads are mechanically or manually mounted on the steps of the pads. When a misalignment occurs, inferior quality of a semiconductor device has been a problem.

Thus, the present disclosure has an object of providing a technology that can suppress a misalignment when an electrode terminal is mounted on a circuit pattern of an insulating substrate.

### Means to Solve the Problem

A semiconductor device according to the present disclosure includes: an insulating substrate on an upper surface of which a circuit pattern is formed; and an electrode terminal including a junction bonded to an upper surface of the circuit pattern, wherein the circuit pattern includes a fitting portion, and the junction of the electrode terminal includes a fitted portion to be fitted into the fitting portion.

### Effects of the Invention

The present disclosure can suppress a misalignment when an electrode terminal is mounted on a circuit pattern of an insulating substrate by fitting a fitted portion of the electrode terminal into a fitting portion of the circuit pattern.

The object, features, aspects, and advantages of this disclosure will become more apparent from the following detailed description and the accompanying drawings.

### BRIEF DESCRIPTION OF DRAWINGS

FIG. 1 is a schematic cross-sectional view illustrating a junction of an electrode terminal included in a semiconductor device according to Embodiment 1 and its vicinity.

FIG. 2 is a schematic cross-sectional view illustrating a junction of an electrode terminal included in a semiconductor device according to Embodiment 2 and its vicinity.

FIG. 3 is a schematic cross-sectional view of a junction of an electrode terminal included in a semiconductor device according to Embodiment 3 and its vicinity before crimping.

FIG. 4 is a schematic cross-sectional view of the junction of the electrode terminal included in the semiconductor device according to Embodiment 3 and its vicinity after crimping.

### DESCRIPTION OF EMBODIMENTS

### Embodiment 1

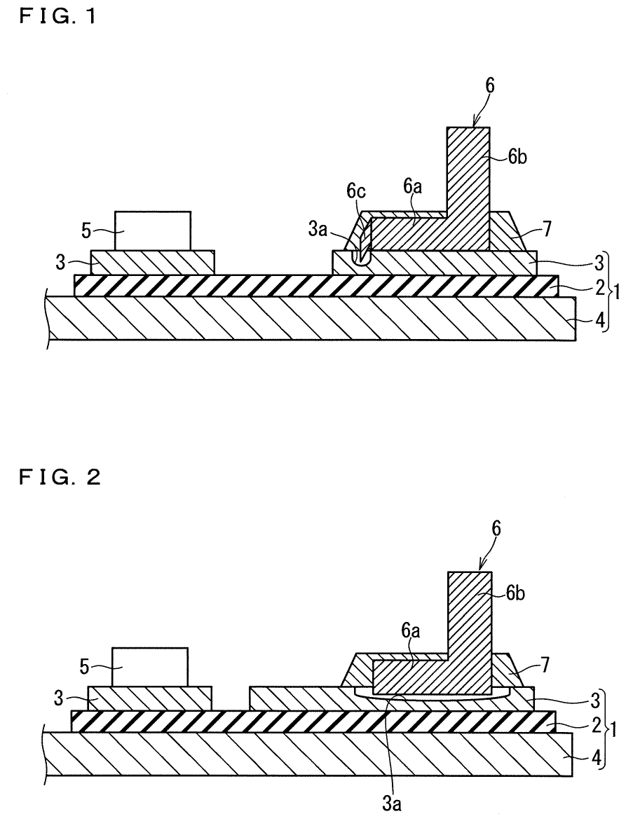

Embodiment 1 will be hereafter described with reference to the drawings. FIG. 1 is a schematic cross-sectional view illustrating a junction 6a of an electrode terminal 6 included in a semiconductor device according to Embodiment 1 and its vicinity.

As illustrated in FIG. 1, the semiconductor device includes an insulating substrate 1, semiconductor elements 5, and the electrode terminal 6. The insulating substrate 1 includes an insulating layer 2, circuit patterns 3, and a base plate 4. The insulating layer 2 is made of, for example, ceramic. The plurality of conductive circuit patterns 3 are disposed on the upper surface of the insulating layer 2. The circuit patterns 3 are made of, for example, Cu. The base plate 4 is disposed on the lower surface of the insulating layer 2.

The electrode terminal 6 is bonded to the upper surface of the circuit pattern 3 through a bonding material 7. Furthermore, a plurality of the semiconductor elements 5 such as an insulated-gate bipolar transistor (IGBT) and a free-wheeling diode (FWDI) are bonded through solder (not illustrated) to the upper surfaces of the circuit patterns 3 adjacent to the circuit pattern 3 to which the electrode terminal 6 is bonded. Each of the adjacent circuit patterns 3 is connected to the circuit pattern 3 through an aluminum wire (not illustrated). Furthermore, the insulating substrate 1, the semiconductor elements 5, and the electrode terminal 6 are protected by a case (not illustrated) and a sealant such as gel (not illustrated). A metal-oxide-semiconductor field effect transistor (MOSFET) may be mounted as the semiconductor element 5, instead of the IGBT. Furthermore, a Schottky diode (SBD) may be mounted instead of the FWDI.

The electrode terminal 6 is electrically connected to the semiconductor elements 5 through aluminum wires (not illustrated). The electrode terminal 6 is made of, for example, Al. The electrode terminal 6 includes the junction 6a formed on one end of the electrode terminal 6, and a bent portion 6b bent upward from the junction 6a. The junction 6a is a portion extending parallel to the upper surface of the circuit pattern 3, and is a portion bonded to the upper surface of the circuit pattern 3. The lower surface of the junction 6a is planar, and is in contact with the circuit pattern 3 across the entire surface. The junction 6a has a drooping surface 6c protruding downward from the outer circumferential surface. The drooping surface 6c is formed across a part or the entirety of the outer circumferential surface of the junction 6a of the electrode terminal 6. When the drooping surface 6c is formed only on a part of the outer circumferential surface of the junction 6a, the drooping surface 6c is preferably formed on the end side of the junction 6a. The end side of the junction 6a means to the left of FIG. 1, that is, opposite to the bent portion 6b.

A recess 3a into which the drooping surface 6c can be fitted is formed in a portion of the upper surface of the circuit pattern 3 to which the electrode terminal 6 is bonded. Specifically, the end portion of the drooping surface 6c is fitted into the recess 3a. The recess 3a is located at a position facing the drooping surface 6c on the upper surface of the circuit pattern 3, and is sized such that the end portion of the drooping surface 6c can be fitted. Fitting the drooping surface 6c into the recess 3a positions the electrode terminal 6 by the circuit pattern 3. Here, the recess 3a corresponds to a fitting portion, and the drooping surface 6c corresponds to a fitted portion.

The bonding material 7 is placed to cover the junction 6a of the electrode terminal 6, and a part of the bent portion 6b. The bonding material 7 is, for example, solder.

Next, a method for forming the drooping surface 6c that is included in the method for manufacturing the semiconductor device will be simply described without drawings. First, a metal plate to be the electrode terminal 6 is disposed in a lower die. Next, the metal plate is punched with a space between the lower die and an upper die facing the lower die to subject the metal plate to plastic deformation. This fabricates the electrode terminal 6 with the drooping surface 6c. In typical semiconductor devices, the electrode terminal 6 is fabricated by minimizing the space between the lower die and the upper die to prevent the drooping surface 6c from being formed. In Embodiment 1, the electrode terminal 6 with the drooping surface 6c is fabricated by widening the space between the lower die and the upper die more than those of the typical semiconductor devices.

The semiconductor device according to Embodiment 1 includes: the insulating substrate 1 on an upper surface of which the circuit pattern 3 is formed; and the electrode terminal 6 including the junction 6a bonded to an upper surface of the circuit pattern 3, wherein the circuit pattern 3 includes a fitting portion, and the junction 6a of the electrode terminal 6 includes a fitted portion to be fitted into the drooping surface 6c. Specifically, the fitting portion is the recess 3a formed in the circuit pattern 3, and the fitted portion is the drooping surface 6c protruding downward from the outer circumferential surface of the junction 6a of the electrode terminal 6, and fitting the drooping surface 6c into the recess 3a positions the electrode terminal 6 by the circuit pattern 3.

Thus, fitting the drooping surface 6c as a fitted portion of the electrode terminal 6 into the recess 3a as a fitting portion of the circuit pattern 3 can suppress a misalignment when the electrode terminal 6 is mounted on the circuit pattern 3 of the insulating substrate 1. This can also suppress a misalignment when the electrode terminal 6 is bonded to the circuit pattern 3.

Forming the drooping surface 6c on the electrode terminal 6 facilitates formation of a solder fillet. This improves not only yield of semiconductor devices but also the durability.

A method for manufacturing the semiconductor device according to Embodiment 1 includes disposing a metal plate to be the electrode terminal 6 in a lower die, and punching the metal plate with a space between the lower die and an upper die facing the lower die to subject the metal plate to plastic deformation and form the drooping surface 6c. Since the drooping surface 6c can be formed in a punching process for fabricating the electrode terminal 6, increase in manufacturing processes can be suppressed.

### Embodiment 2

Next, a semiconductor device according to Embodiment 2 will be described. FIG. 2 is a schematic cross-sectional view illustrating the junction 6a of the electrode terminal 6 included in the semiconductor device according to Embodiment 2 and its vicinity. In Embodiment 2, the same reference numerals are assigned to the same constituent elements described in Embodiment 1, and the description thereof will be omitted.

As illustrated in FIG. 2, the junction 6a of the electrode terminal 6 does not include the drooping surface 6c (see FIG. 1), and the entire lower end portion of the junction 6a functions as a fitted portion.

The recess 3a formed in the circuit pattern 3 is sized such that the entire lower end portion of the junction 6a can be fitted. The maximum depth of the recess 3a is smaller than or equal to half the thickness of the circuit pattern 3. Preferably, the maximum depth of the recess 3a is one quarter or more and one half or less of the thickness of the circuit pattern 3.

In the semiconductor device according to Embodiment 2, the fitting portion is the recess 3a formed in the circuit pattern 3, the maximum depth of the recess 3a is smaller than or equal to half the thickness of the circuit pattern 3, the fitted portion is the lower end portion of the junction 6a of the electrode terminal 6, and fitting the lower end portion of the junction 6a of the electrode terminal 6 into the recess 3a positions the electrode terminal 6 by the circuit pattern 3.

Thus, fitting the lower end portion of the junction 6a as a fitted portion of the electrode terminal 6 into the recess 3a as a fitting portion of the circuit pattern 3 can suppress a misalignment when the electrode terminal 6 is mounted on the circuit pattern 3 of the insulating substrate 1. This can also suppress a misalignment when the electrode terminal 6 is bonded to the circuit pattern 3.

Furthermore, reduction in the thickness of a portion of the circuit pattern 3 at which the electrode terminal 6 is bonded reduces the thermal resistance from the electrode terminal 6 to radiating fins (not illustrated) to be attached to the lower surface of the base plate 4. This facilitates dissipating the heat generated in the electrode terminal 6 through the radiating fins.

### Embodiment 3

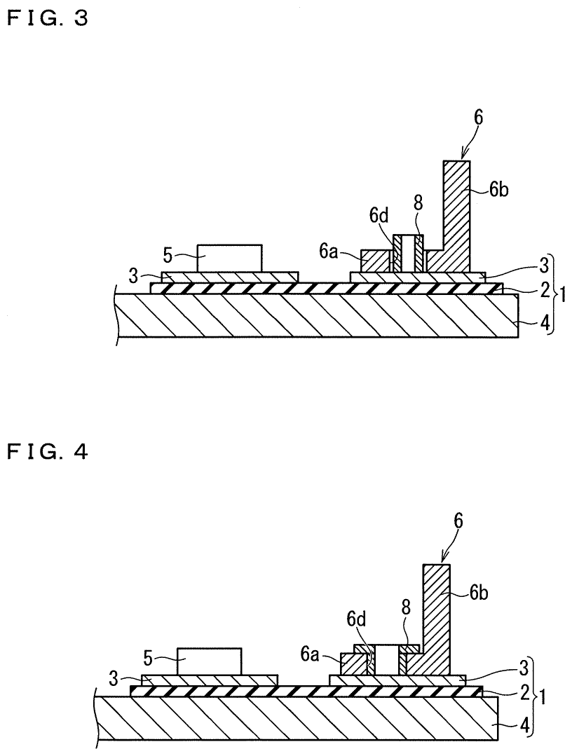

Next, a semiconductor device according to Embodiment 3 will be described. FIG. 3 is a schematic cross-sectional view of the junction 6a of the electrode terminal 6 included in the semiconductor device according to Embodiment 3 and its vicinity before crimping. FIG. 4 is a schematic cross-sectional view of the junction 6a of the electrode terminal 6 included in the semiconductor device according to Embodiment 3 and its vicinity after crimping. In Embodiment 3, the same reference numerals are assigned to the same constituent elements described in Embodiments 1 and 2, and the description thereof will be omitted.

As illustrated in FIG. 3, a protrusion 8 protruding upward is formed on the upper surface of the circuit pattern 3 in Embodiment 3. The protrusion 8 is formed into a cylindrical column or a cylinder, and is formed integrally with the circuit pattern 3. The vertical length of the protrusion 8 is greater than the thickness of the junction 6a of the electrode terminal 6.

The junction 6a of the electrode terminal 6 includes a through hole 6d into which the protrusion 8 can be fitted. The diameter of the through hole 6d is formed slightly larger than that of the protrusion 8 to allow deformation of the protrusion 8 when the end portion of the protrusion 8 is crimped. Fitting the protrusion 8 into the through hole 6d positions the electrode terminal 6 by the circuit pattern 3. After the positioning, the end portion of the protrusion 8 is crimped while the end portion of the protrusion 8 is fitted into the through hole 6d as illustrated in FIG. 4. This bonds the electrode terminal 6 to the circuit pattern 3 without using the bonding material 7 (see FIG. 1). Here, the protrusion 8 corresponds to a fitting portion, and the through hole 6d corresponds to a fitted portion.

Next, a method for crimping the end portion of the protrusion 8 that is included in the method for manufacturing the semiconductor device will be simply described. First, the electrode terminal 6 is disposed on the circuit pattern 3 such that the through hole 6d of the junction 6a is fitted into the protrusion 8 on the circuit pattern 3 as illustrated in FIG. 3. Next, a load is applied to the end portion of the protrusion 8 using an ultrasonic bonding tool (not illustrated). Consequently, the end portion of the protrusion 8 is crimped as illustrated in FIG. 4.

As described above, in the semiconductor device according to Embodiment 3, the fitting portion is the protrusion 8 formed on the circuit pattern 3, the fitted portion is the through hole 6d formed in the junction 6a of the electrode terminal 6, and fitting the through hole 6d into the protrusion 8 positions the electrode terminal 6 by the circuit pattern 3.

Thus, fitting the through hole 6d of the junction 6a as a fitted portion of the electrode terminal 6 into the protrusion 8 as a fitting portion of the circuit pattern 3 can suppress a misalignment when the electrode terminal 6 is mounted on the circuit pattern 3 of the insulating substrate 1. This can also suppress a misalignment when the electrode terminal 6 is bonded to the circuit pattern 3.

Since the end portion of the protrusion 8 is crimped while the end portion of the protrusion 8 is fitted into the through hole 6d, the electrode terminal 6 can be bonded to the circuit pattern 3 without using the bonding material 7.

Even when the electrode terminal 6 made of Al is bonded to the circuit pattern 3 made of Cu, which has conventionally been difficult without increasing the temperature, electrical connection of the electrode terminal 6 to the circuit pattern 3 will be facilitated. Furthermore, crimping the end portion of the protrusion 8 while the end portion of the protrusion 8 is fitted into the through hole 6d improves the bonding reliability between the electrode terminal 6 and the circuit pattern 3.

Since the protrusion 8 is integrated with the circuit pattern 3, bonding the protrusion 8 to the circuit pattern 3 is unnecessary. This further improves the bonding reliability between the electrode terminal 6 and the circuit pattern 3.

Since the protrusion 8 is formed into a cylindrical column or a cylinder, the protrusion 8 can be brought into intimate contact with the through hole 6d through uniform deformation of the protrusion 8. This further strengthens the bonding of the electrode terminal 6 to the circuit pattern 3.

While the present disclosure is described in detail, the foregoing description is in all aspects illustrative and does not restrict the present disclosure. Thus, numerous modifications that have yet been exemplified will be devised.

Embodiments can be freely combined, and appropriately modified or omitted.

### EXPLANATION OF REFERENCE SIGNS

1 insulating substrate, 3 circuit pattern, 3a recess, 6 electrode terminal, 6a junction, 6c drooping surface, 6d through hole, 8 protrusion.

1. A semiconductor device, comprising:
an insulating substrate on an upper surface of which a circuit pattern is formed; and
an electrode terminal including a junction bonded to an upper surface of the circuit pattern,
wherein the circuit pattern includes a fitting portion, and
the junction of the electrode terminal includes a fitted portion to be fitted into the fitting portion.

2. The semiconductor device according to claim 1,
wherein the fitting portion is a recess formed in the circuit pattern,
the fitted portion is a drooping surface protruding downward from an outer circumferential surface of the junction of the electrode terminal, and
fitting the drooping surface into the recess positions the electrode terminal by the circuit pattern.

3. The semiconductor device according to claim 1,
wherein the fitting portion is a recess formed in the circuit pattern,
a maximum depth of the recess is smaller than or equal to half a thickness of the circuit pattern,
the fitted portion is a lower end portion of the junction of the electrode terminal, and
fitting the lower end portion of the junction of the electrode terminal into the recess positions the electrode terminal by the circuit pattern.

4. The semiconductor device according to claim 1,
wherein the fitting portion is a protrusion formed on the circuit pattern,
the fitted portion is a through hole formed in the junction of the electrode terminal, and
fitting the through hole into the protrusion positions the electrode terminal by the circuit pattern.

5. The semiconductor device according to claim 4,
wherein an end portion of the protrusion is crimped while the end portion of the protrusion is fitted into the through hole.

6. The semiconductor device according to claim 4,
wherein the protrusion is integrated with the circuit pattern.

7. The semiconductor device according to claim 4,
wherein the protrusion is formed into a cylindrical column or a cylinder.

8. A method for manufacturing the semiconductor device according to claim 2, the method comprising
disposing a metal plate to be the electrode terminal in a lower die, and punching the metal plate with a space between the lower die and an upper die facing the lower die to subject the metal plate to plastic deformation and form the drooping surface.

9. A method for manufacturing the semiconductor device according to claim 5, the method comprising
disposing the electrode terminal on the circuit pattern so that the through hole of the junction is fitted into the protrusion of the circuit pattern, and applying a load to the end portion of the protrusion using an ultrasonic bonding tool to crimp the end portion of the protrusion.

10. The semiconductor device according to claim 5,
wherein the protrusion is integrated with the circuit pattern.

11. The semiconductor device according to claim 5,
wherein the protrusion is formed into a cylindrical column or a cylinder.

12. The semiconductor device according to claim 6,
wherein the protrusion is formed into a cylindrical column or a cylinder.

13. The semiconductor device according to claim 10,
wherein the protrusion is formed into a cylindrical column or a cylinder.
